(19) United States
(12) Patent Application Publication
(10) Pub. No.: US 2021/0358288 A1
(43) Pub. Date: Nov. 18, 2021

(54) TOOL MODULE LOADING AND OPTICAL REGISTRATION FOR AN APPARATUS FOR MANUFACTURING MULTILAYER CIRCUIT BOARDS

(71) Applicant: Yasser Boumenir, Brooklyn, NY (US)

(72) Inventor: Yasser Boumenir, Brooklyn, NY (US)

(21) Appl. No.: 17/064,217

(22) Filed: Oct. 6, 2020

Related U.S. Application Data
(60) Provisional application No. 62/911,366, filed on Oct. 6, 2019.

(51) Int. Cl. G08B 21/18; G08B 5/36

(52) U.S. Cl. CPC G08B 21/18; G08B 5/36

(57) ABSTRACT

An apparatus for manufacturing printing circuit boards is provided. The apparatus includes a microcontroller, power supply, two-dimensional stage, laser, and one or more chemical treatment tanks. The apparatus may include a mutlifunctional print module, or multiple independent tool modules capable of being exchanged, to perform various different processes on a substrate on the same build plate, and may include mechanical means for transporting the substrate during different stages between the build plate, chemical processing chamber(s), and a pressing chamber. A rapid, auto-calibrating loading system may be provided for the independent tool modules, and a camera provided for an optical registration operation.

### CROSS-REFERENCE TO RELATED APPLICATION

This application claims priority to U.S. Provisional Patent Application Ser. No. 62/911,366 entitled “TOOL MODULE LOADING AND OPTICAL REGISTRATION FOR AN APPARATUS FOR MANUFACTURING MULTILAYER CIRCUIT BOARDS” and filed Oct. 6, 2019.

### FIELD OF THE INVENTION

The present invention relates generally to an apparatus for creating printed circuit boards (PCBs). More particularly, this invention pertains to an apparatus for developing and creating prototype multilayer printed circuit boards in an integrated chasis unit including a multi-functional print head.

### BACKGROUND

The general process of creating multilayered printed circuit boards is an arduous and labor intensive process. Often it is including the creation of phototools which are used to image a pattern onto a photoresist that is laminated on a copper foil of the required weight of the design which is laminated onto a woven glass cloth impregnated with epoxy resin, known as a prepreg.

These laminates are defined as a panel and have tooling holes so they can be aligned with a common datum or coordinate system. After imaging the design onto the substrate, the panel is then developed where the unpolymerized polymers are then removed, thereby leaving the desired structures. The panel is then chemically etched to remove the undesired copper structures.

The panel is then drilled and stacked onto another previously processed panel where a multilayer structure is then made. These layers can then be electroplated thereby electrically connecting them. The process is continued until a desired multilayered structure is made, after which it is aligned and placed into a heated chamber with a hydraulic press.

The hydraulic press would then apply an even pressure onto the multilayer structure which would evenly spread the heated epoxy resin of the prepreg layers with a combination of a vacuum and several hours of cooking, the epoxy becomes elastic and flows across the various layers and is cured to create a stiff multilayer circuit board. This process of creating multilayered circuit boards requires several machines and assembly process.

### SUMMARY

Aspects of the present invention provide an apparatus for a new method in manufacturing multilayer circuit boards by means of automating the general method of manufacturing multilayer circuit boards comprising of several unique machines into one machine with unique tooling heads that perform a similar function to the previously mentioned unique machines.

The apparatus includes a multifunctional tool head that can move in z axis which is precisely driven by stepper motors on one dimension, which is built onto the frame of a mobile platform which is also precisely driven by stepper motors in the orthogonal dimension, creating an x-y stage. The multifunctional tool head is coupled with a digital optical system that is used for registration as well as identifying and creating work coordinate systems for the tool changer, allowing it to perform various operations such as drilling, heating and pressing laminates and panels, placing rivets for vias into panels, as well as picking and placing panels.

The laminated coating this is placed onto the copper substrate is a unique blend of polymers and photo-initiators. The structure of the resin changes and strengthens with the activation of photons emitted at a specific frequency, which then creates a chain reaction of free radicals that propagate and harden each polymer strand and binds to the copper surface. This procedure is continued until a copper substrate with a surface that resembles the circuit schematic is developed. After which, a chemical washing removes unhardened polymer resin from the developed copper circuit board.

A final chemical etchant removes the non-doped copper regions to produce the final printed circuit board product. The apparatus houses a power supply that powers the two-dimensional stage as well as the pumps and temperature controlled tanks that perform the chemical washing and etching of the developed circuit board. The apparatus is controlled by CAD modeling software via an interface to a main computer.

The apparatus consists of a chamber where panels of photoresist are laminated onto copper foils that are adhered onto a prepreg. These panels may be double sided, and of various thickness of prepreg as well as varying copper foils thickness.

The complete apparatus, may include at least one microcontroller that will interface between the stepper motors that control the movement of the platform, as well as the ejection of both the curable resin and chemical etchant via a set of DC motor pumps. The microcontroller will also communicate to a host computer via a USB interface. The computer will use guide the platform in its movement by a CAD/CAM software.

### BRIEF DESCRIPTION OF THE DRAWINGS

FIG. 1 is a perspective view of a printed circuit board apparatus according to an embodiment.

FIG. 2 is a perspective view of internal components of the printed circuit board apparatus of FIG. 1.

FIGS. 3A-3C shows a printed circuit board in various stages of development using the printed circuit board apparatus of FIG. 1.

FIG. 4 is a perspective view an exemplary developing and etching chamber.

FIG. 5 shows a printed circuit board apparatus according to another embodiment.

FIGS. 6A-6C show a flowchart describing an exemplary process for generating a printed circuit board using the printed circuit board apparatus of FIG. 5.

FIG. 7 is a flowchart describing an imaging process according to an embodiment.

FIG. 8 is a flowchart describing a photoresist developing routine according to an embodiment.

FIG. 9 is a flowchart describing a chemical etching process according to an embodiment.

FIG. 10 is a flowchart describing a drilling routine according to an embodiment.

FIG. 11 is a flowchart describing a hole drilling routine according to an embodiment.

FIG. 12 is a flowchart describing a via placement routine according to an embodiment.

FIG. 13 is a flowchart describing a via/rivet plunging routine according to an embodiment.

FIG. 14 is a flowchart describing a panel flipping routine according to an embodiment.

FIG. 15 is a flowchart describing a via plunging routine according to an embodiment.

FIG. 16 is a flowchart describing a via flattening routine according to an embodiment.

FIGS. 17A and 17B describe an exemplary imaging routine which may be used for generating a solder mask or silk screen according to an embodiment.

FIGS. 18A to 18D a perspective views of various tool modules according to an embodiment.

FIGS. 19A and 19B shows a perspective view of a gantry for moving the tool head over the chambers according to an embodiment.

FIG. 20 shows a perspective view of a tool module receptacle on the tool head according to an embodiment.

FIG. 21 shows a generic mounting head different types of tool modules according to an embodiment.

FIG. 22 shows a point selection operation by a user in an optical registration according to an embodiment.

FIG. 23 is a flowchart describing an optical registration operation according to an embodiment.

### DETAILED DESCRIPTION

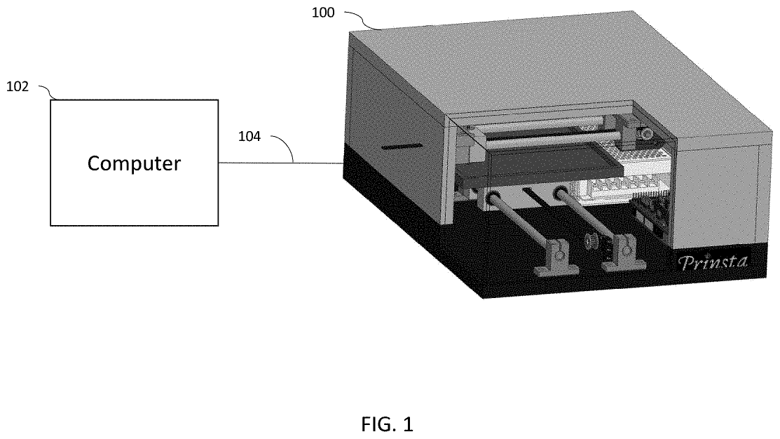

FIG. 1 shows a circuit board printer apparatus 100 according to an embodiment. The circuit board printer may be attached to a computer 102 via a serial interface 104.

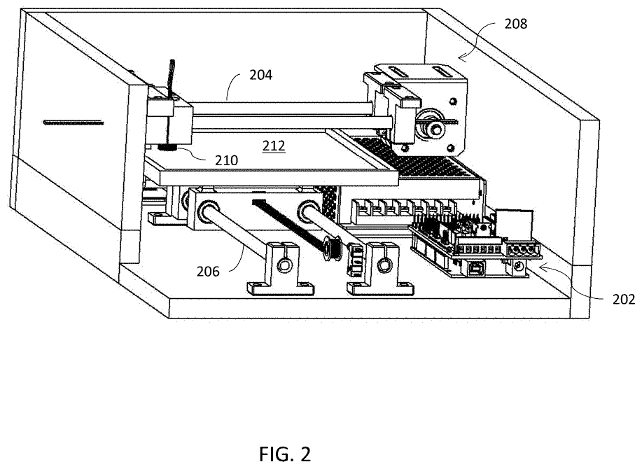

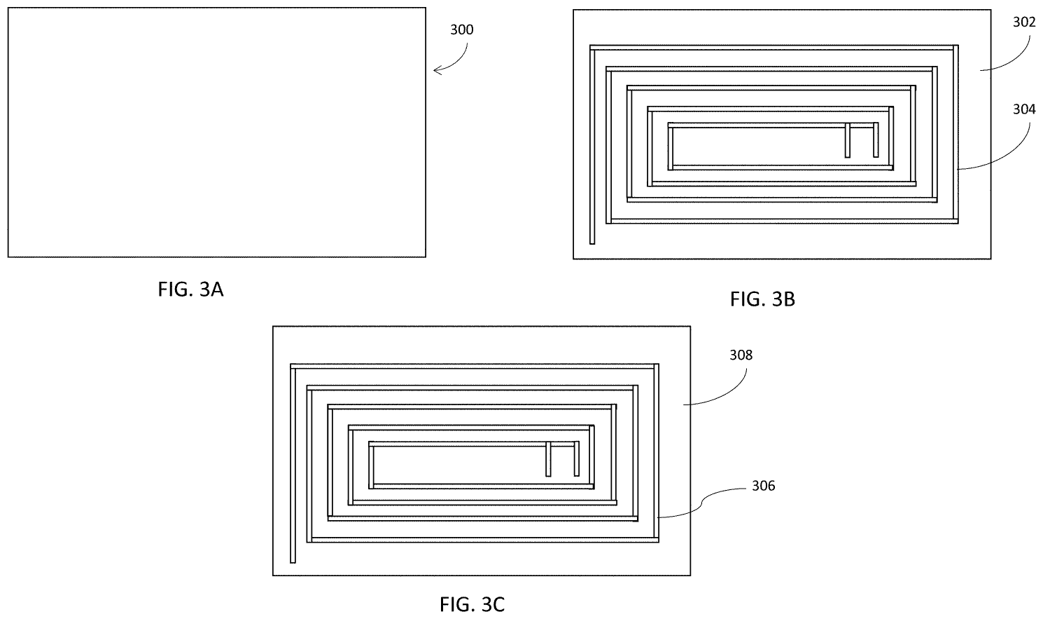

FIG. 2 shows internal components of the circuit board printer 100. The circuit board printer includes a microcontroller 202 with supporting circuitry powered by a power supply that is used to control the movement of both x-dimension 204 and y-dimension 206 dimension of a multifunctional print head with the use of stepper motors 208. The multifunctional print head may include a laser 210 is used to develop a doped copper substrate 300, shown in FIG. 3A. The multifunctional print head may also include other modules, such as a drilling module, plunging module, etc.

The computer may be loaded with Gerber files representing the PCB design, which is a common file format used by PCB industry software to describe the printed circuit board images, e.g., copper layers, solder mask, legend, drill data, etc.. The Gerber files may then be used to by a CAD drawing program to control the microcontroller 202 to control the various components of the circuit board printer to perform the various steps of the process.

In an embodiment, the doped copper (prepreg) substrate 300 would be placed onto the platform 212 in the circuit board printer from a container that holds the previously described prepreg, and loaded onto a build plate by a multifunctional print head after loading the pick and place module powered by a vacuum pump.

After placing the prepreg substrate onto the build plate, the multifunctional print head would use its optical system to detect feature points, which may be fiducials on the corners of the prepreg, to create the virtual coordinate system.

Upon computing the 2-dimensional transforms, the multifunctional print head would then load the laser module 210, which is then used to image the desired pattern onto the laminate. The microcontroller 202 would receive input from the host computer via a serial interface or other protocol. The computer would instruct the microcontroller to perform intricate movements using the stepper motors on both the x and y axes of the printer apparatus while imaging the prepreg via laser beam. The laser beam may also be moved via a galvo system.

Upon finishing the imaging sequence, the prepreg is then transferred from the build plate to a flipping station via the multifunctional print, which then flips the prepreg onto its underside. The prepreg is then loaded back onto the build plate where it is then located by the optical system. The algorithm of imaging the pattern onto the substrate, as mentioned previously, is then performed once more to create a double sided prepreg.

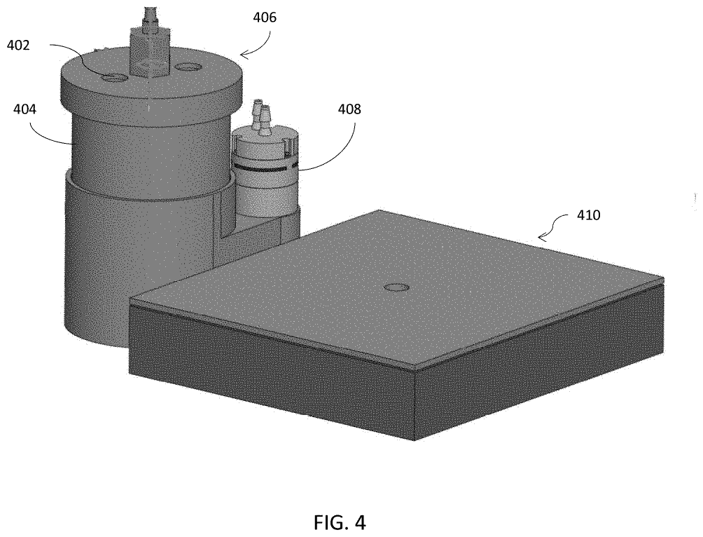

After completing the printing process, the multifunctional print head loads the imaged panel into the developing and etching chamber, shown in FIG. 4. The microcontroller controls the circuit board printer 100 to measure the temperature using sensors 402 of the chemical mixture in the tank 404 and heat it using a heating element 406 to the desired temperature. whereby it is then pumped by pump 408 out of the tank and sprayed onto the developed panel.

The developer is designed in such a manner to remove unpolymerized polymers from the surface of the prepreg, whereby leaving the image of the desired pattern onto the prepreg.

The microcontroller then loads warm water to spray onto the prepreg thereby washing away the developer solution. The chamber is then drained. This processing would then create a circuit board that is shown in FIG. 3B where the copper substrate is exposed 302 but the desired signal path 304 is not.

After developing the prepreg, the microcontroller then loads the chemical etchant into the chamber, and begins spraying the developed prepreg. As is it being sprayed and dripped back into the chamber, the microcontroller is then measuring the temperature, pH, and oxide concentrations and balancing it with a standard PID control algorithm. The combined data of the change of oxide concentrations, pH, and temperature as well as imaging of the panel would dictate when to stop the developing or etching process via an algorithm. Upon completion, the microcontroller would spray the panel with a water solution, and then emptied the chamber. The multifunctional print head would then pick up the panel and place it back into the build plate for further processing. This processing would then create the final product which is shown in FIG. 3C as the prototype with the intended design, containing the desired copper signal path 306 onto the substrate 308.

The multifunctional print head would then load a drilling module to drill through holes or other structures pertaining to the design. After the drilling is finished, the multifunctional print head would then load a via placement module. The via placement module would then place rivets thereby creating vias in the appropriate holes. The vias may be of the nature of a blind, through-hole or other type. The multifunctional print head would then place a generic panel on top of the panel thereby creating a seal on top of the rivets. The panel is then moved to the flipping station, where it is then flipped and placed back onto the build plate.

The multifunctional print head would then load a via plunging module. Depending on the rivet size, the module may load the appropriate plunger. The module would generate the appropriate load to deform the rivet structure thereby creating a mechanical and electrical connection. A flat plunger is then loaded as a final operation of flattening all rivets. This completes the creation of a layer and panel.

Assuming the design is of the nature of a multilayer PCB, the circuit board may either cached into the pressing chamber, or loaded back onto the build plate for placing solder mask and or silk screen.

In the event of creating complex via structures, such as blind vias, the apparatus would cache a layer in the pressing chamber, as well as the prepreg loading chamber, while performing stacking operations in the build plate.

In the event the desired circuit board is only two layers, upon completing the structure, the apparatus would then image the solder mask and silkscreen.

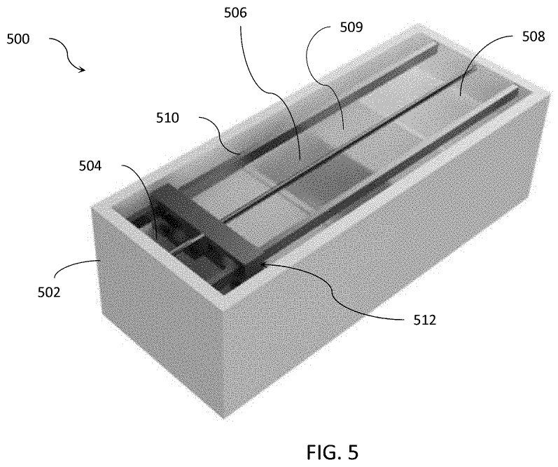

FIG. 5 shows a circuit board printer 500 according to another embodiment. The circuit board printer includes a housing 502, prepreg loading chamber 504, a chemical processing chamber 506, and a pressing chamber 508. A platform 509 including a build plate and other components shown in FIG. 2 may be interposed between the chemical processing chamber 506 and the pressing chamber 509. A rail system 510 including a motorized cartridge 512 may be used to transport a prepreg between the prepreg loading chamber, build plate, chemical processing chamber and the pressing chamber.

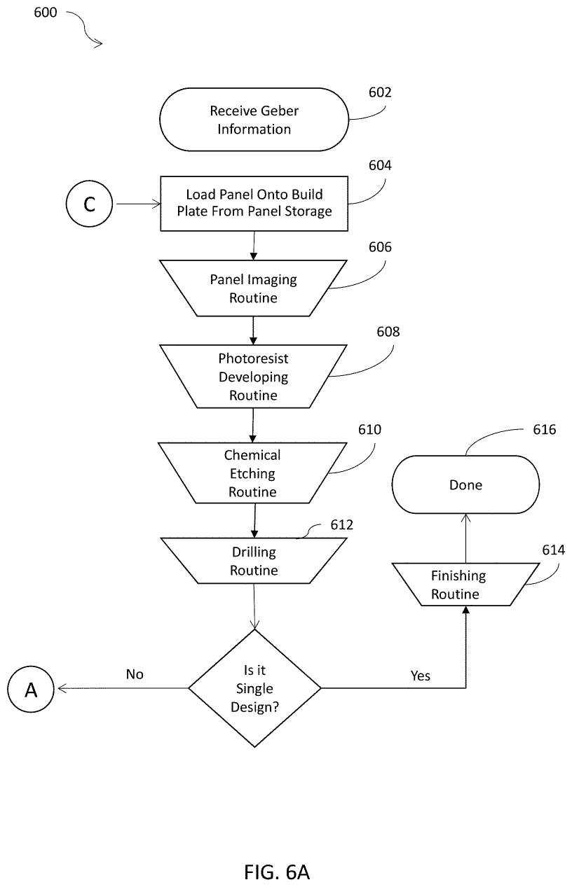

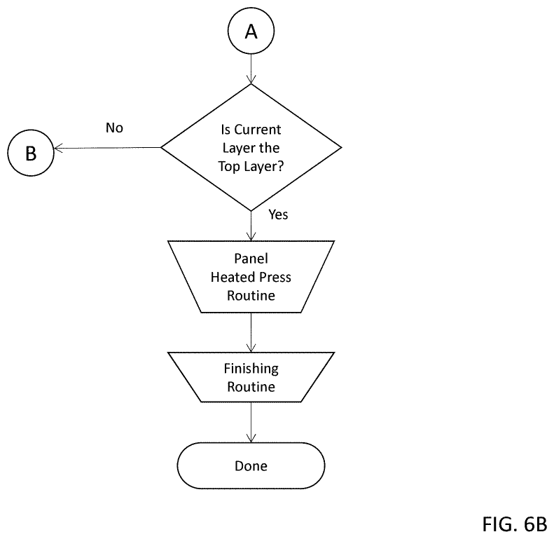

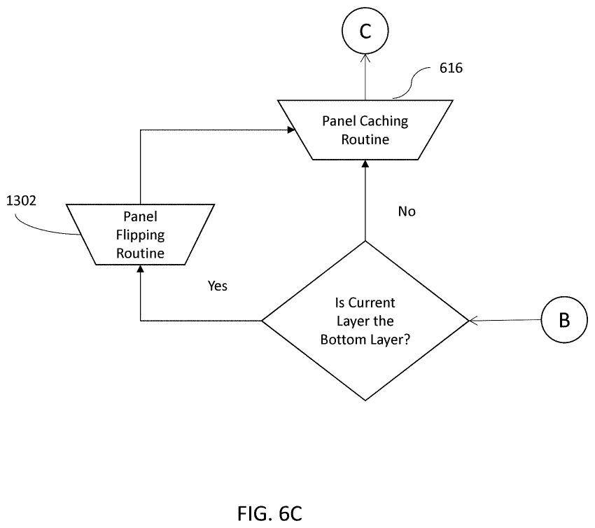

FIGS. 6 to 17 describe an exemplary circuit board printing process 600 for single and multilayer PCBs using printer 500. The general steps are more fully described above in regard to the use of exemplary printer 100.

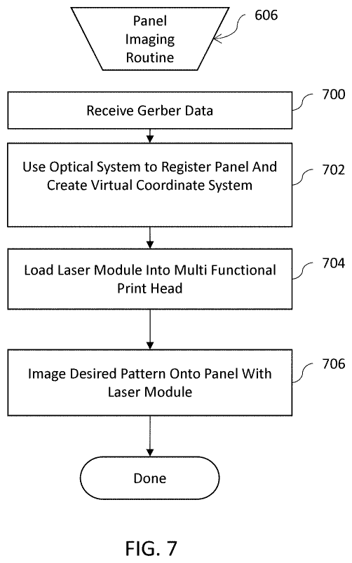

As shown in FIG. 6A, the microprocessor receives Gerber information 602 from the computer 102. The cartridge 512 removes a prepreg substrate from the loading chamber 504 and transports and loads it onto the build plate 604. A panel imaging routine is then performed 606, described in FIG. 7. The microcontroller receives Gerber data regarding the imaging process 700. The optical system is then used to register the prepreg panel and create a virtual coordinate system 702. The multifunctional print head then loads the laser module 704, and creates the desired pattern onto the panel using the laser module 706.

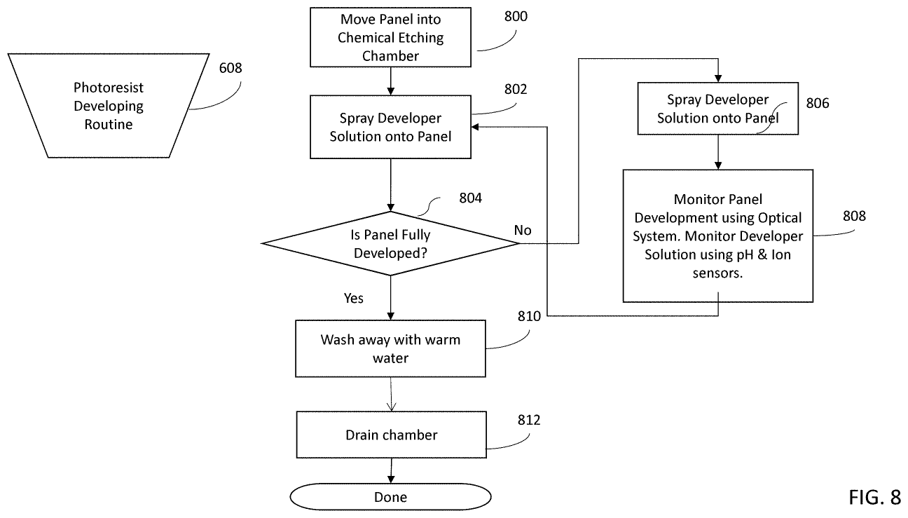

Next, the cartridge moves the panel to the chemical processing chamber 506, and a photoresist developing routine 608 is performed, as shown in FIG. 8. After the panel is moved into the chemical etching chamber 800, a developer solution is spayed onto the panel 802. If it is determined 804 that the panel is not fully developed, additional developer solution may be sprayed onto the panel 806, and development proceeds using an optical system, including monitoring the pH and ion characteristics of the developing resist 808, and this process repeated until it is determined that the panel is fully developed. At that point, the undeveloped resist is washed away with warm water 810, and the chamber drained 812.

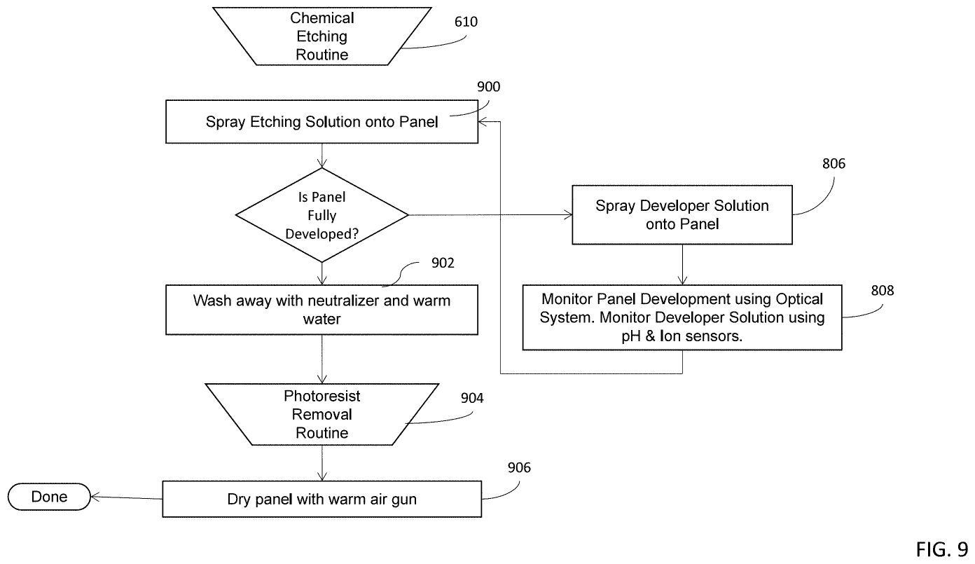

A chemical etching process 610 shown in FIG. 9 is performed next. An etching solution is sprayed onto the panel 900. If it is determined that the panel is not fully developed, additional developer solution may be sprayed onto the panel 806, and development proceeds using an optical system, including monitoring the pH and ion characteristics of the developing resist 808, and the panel is sprayed with the etching solution again 900. This process repeated until it is determined that the panel is fully developed. At that point, the etching solution is washed away with neutralizer and warm water 902, and a photoresist removal process 904 is performed, in which steps 802 to 812 from the photoresist development process in FIG. 8 are repeated. The panel is then dried with a warm air gun 906.

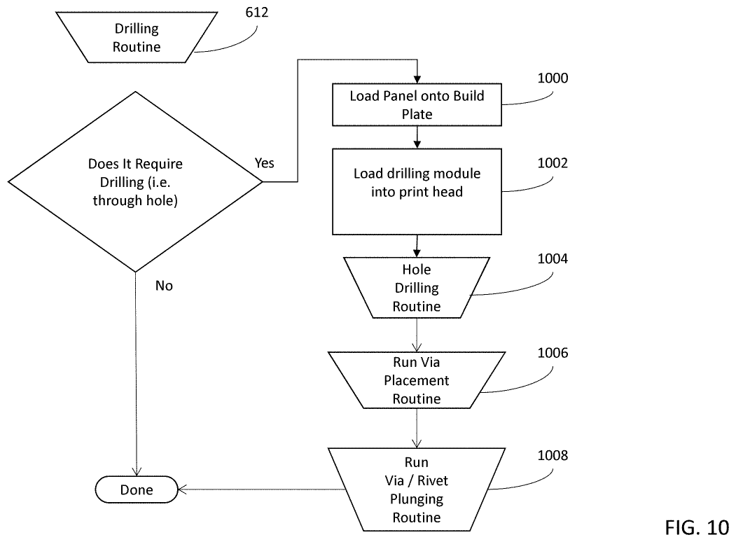

After the chemical etching process 610 is complete, it determined whether a drilling routine 612, described in reference to FIG. 10, needs to be performed. If not, and if it is a single design, i.e, one sided one layer, it is determined whether any processes in a finishing routine 614, described below, needs to be performed. If not, the operation is complete.

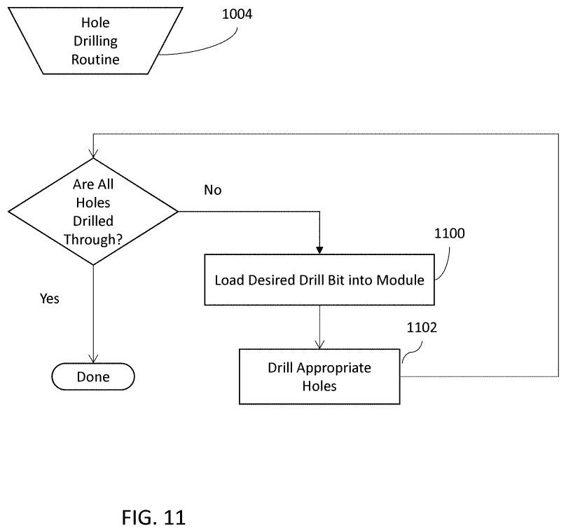

FIG. 10 shows the drilling routine 612. The carriage reloads the panel onto the build plate 1000, and the multi-function print head loads a load drilling module 1002. A hole drilling routine 1004 described in FIG. 11 is then performed, in which the desired drill bit is loaded into the module 1100 and appropriate holes for that drill bit size are drilled 1102 and this process repeated until all holes are drilled.

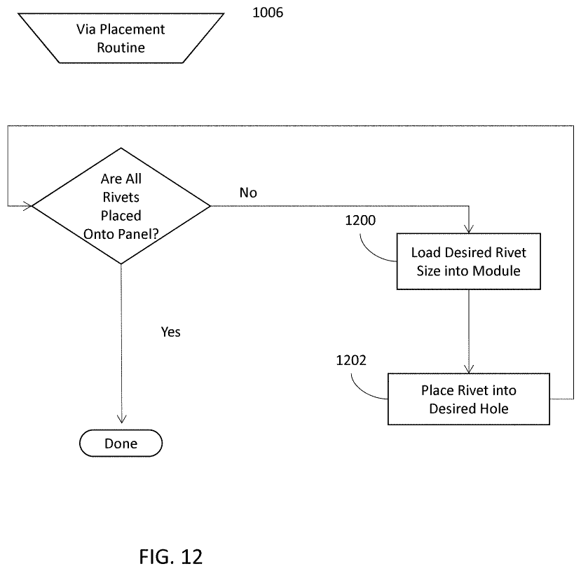

A via placement routine 1006 described in FIG. 12 is then performed, in which the desired rivet size is loaded into the module 1200 and appropriate rivets are placed in the desired rivet holes 1202 and this process repeated until all rivets are placed onto the panel.

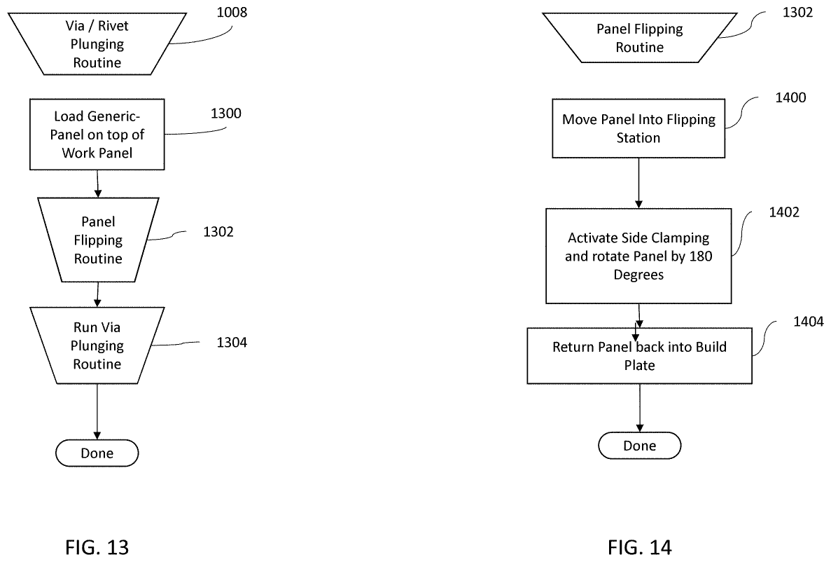

After the rivets are placed, a via/rivet plunging routine 1008, shown in FIG. 13, is performed. A generic panel is loaded on top of the work panel 1300. A panel flipping routine 1302 is then performed, as shown in FIG. 14, in which the panel is moved into a flipping station 1400 and a side clamping mechanism is activated to clamp the panel and rotate it 180 degrees 1402. The panel is then returned to the build plate 1404.

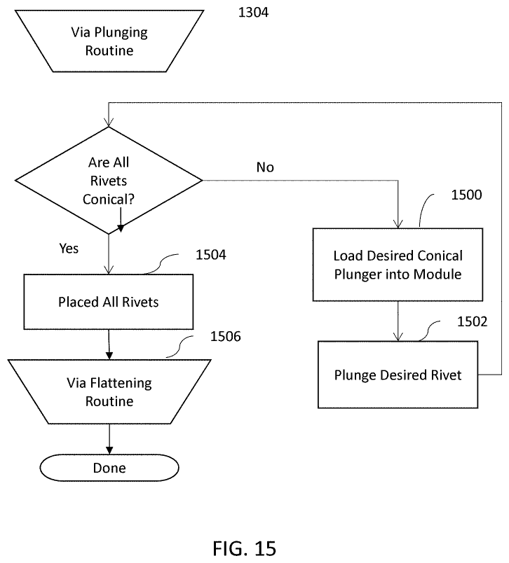

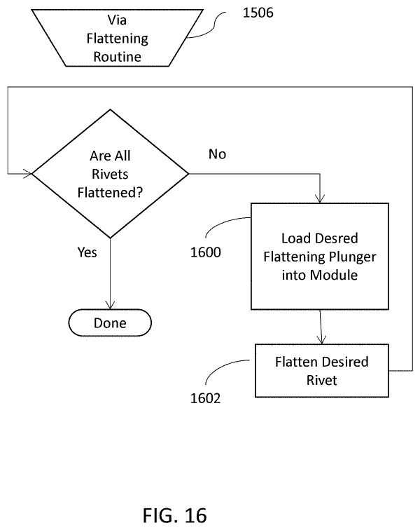

Returning to FIG. 13, a via plunging routine is then performed, as shown in FIG. 15. A desired conical plunger is loaded into the module 1500 and desired rivet(s) are plunged 1502. This operation is repeated until a rivets are conical. When all rivets are placed 1504, a via flattening routine 1508 shown in FIG. 16, is performed.

A desired flattening plunger is loaded into the module 1600 and desired rivet(s) are flattened 1602. This operation is repeated until a rivets are flattened, a which point the drilling routine 612 is complete.

The printer 500 is capable of processing multiple layer PCBs. Generally, the bottom layer is processed before the top layer of each panel in the multi-layer PCB, and when the top layer of the top panel in the stack is processed, the panels are stacked and pressed heated to form the final multilayer PCB.

Returning to FIG. 6B, if the drilled panel is not the top panel, and moving to FIG. 6C, but is top layer, the flipping routine 1302 shown in FIG. 14 is performed, and then a panel caching routine 618 is performed. Otherwise, the flipping routine is skipped. If necessary, the other side of the panel may be processed by returning to step 602 of the process, as shown in FIG. 6A.

If the drilled panel is the top panel, the stack of finished stack of layers is transferred to the pressing chamber 508, and a panel heated press routine 620 performed.

A finishing operation 614 including optional operations may then be performed in the following order: solder mask imaging, silk screen imaging, automated optical inspection, and automated continuity inspection.

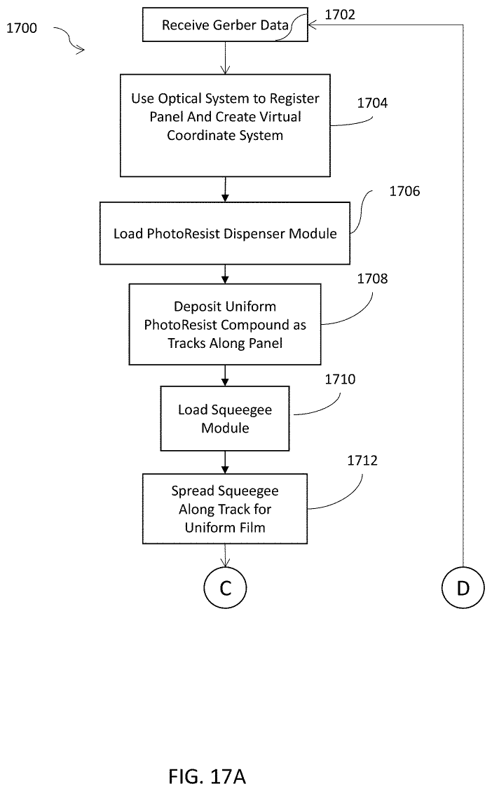

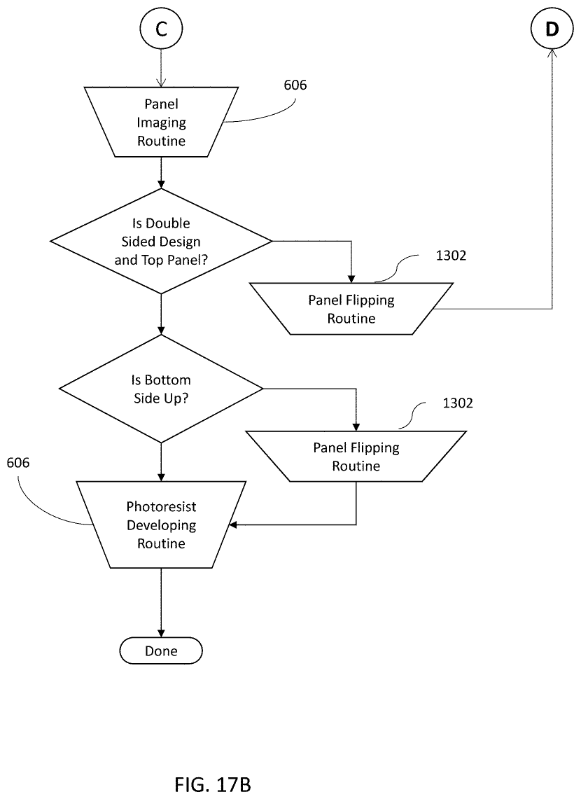

FIGS. 17A and 17B describe an exemplary imaging routine 17 which may be used for generating a solder mask or silk screen. The microcontroller receives Gerber data 1702. The optical system is used to register the panel and create a virtual coordinate system 1704. The multi-functional print head loads a photoresist dispenser module 1706, and deposits a uniform photoresist compound as tracks along the panel 1808. Next the squeegee module is loaded 1710 and used to spread the photoresist compound along the tracks to form a uniform film 1712.

A panel imaging routine 606 described above is then performed. If it is a double-sided design and the top panel, the panel is flipped 1302 and the process returns to step 1702. If not, and the bottom side is up, the panel is flipped 1302, and a photoresist developing routine 608 performed. If the top side is facing up, the flipping operation is skipped.

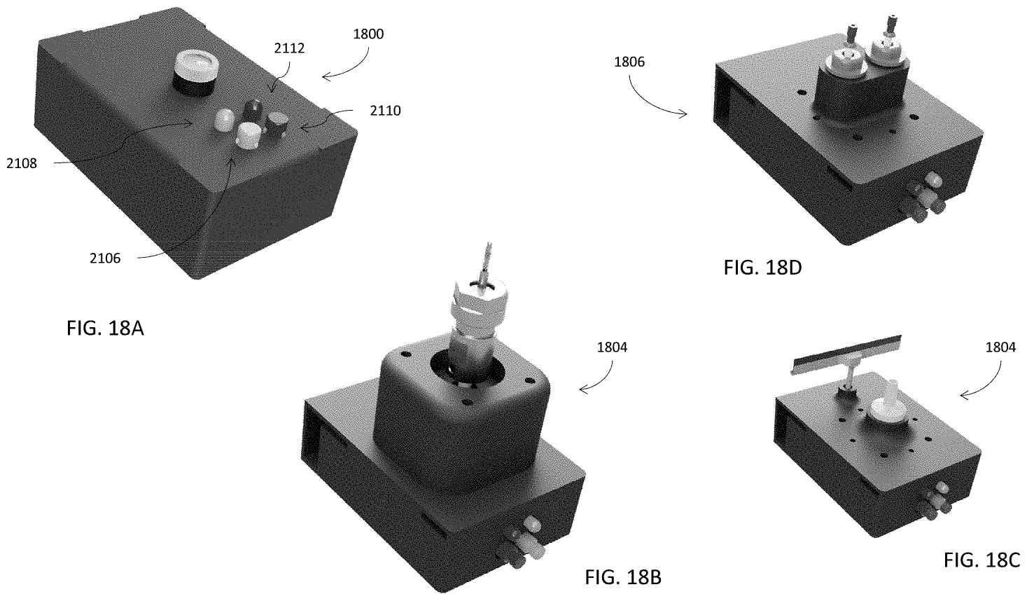

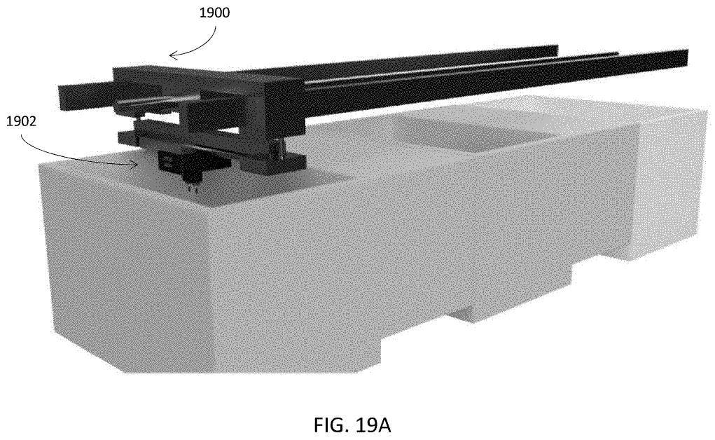

In an embodiment, the multifunctional print head may be replaced by individual-use modules may be manually interchanged in a tool module receiver for different processes. For example, FIG. 18A shows a laser module 1800, FIG. 18B shows a drill module 1802, FIG. 18C shows a squeegee module 1804, and FIG. 18D shows a vacuum-operated pick-and-place module 1806.

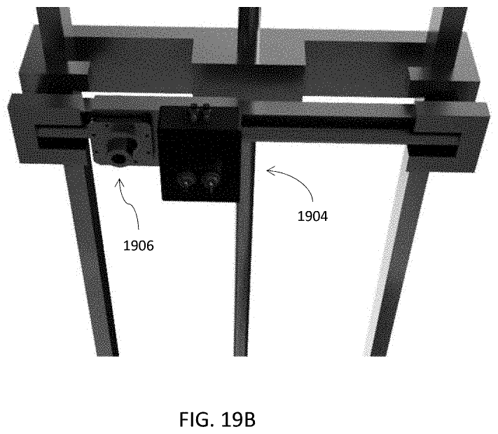

FIG. 19A shows a gantry 1900 for moving the tool head 1902 over the chambers and platform in x-, y-, and z-directions. As shown in FIG. 19B, in this example, a pick-and-place module 1904 is attached to a tool module receiver, and a camera 1906 is provided for transmission of images to the computer.

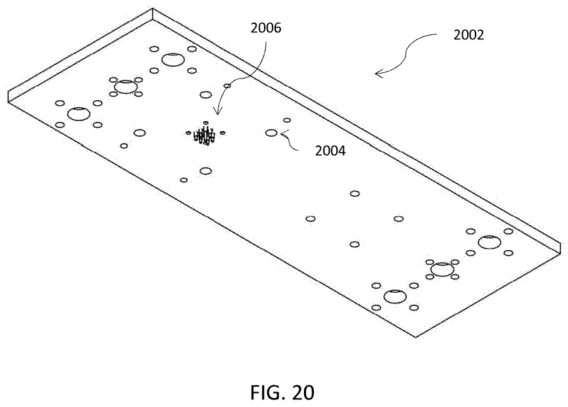

FIG. 20 shows a tool module receptacle on the tool head 1902 according to an embodiment. A plate 2002 includes screw holes 2004 for accepting threaded rods and a number of electrical contacts 2006.

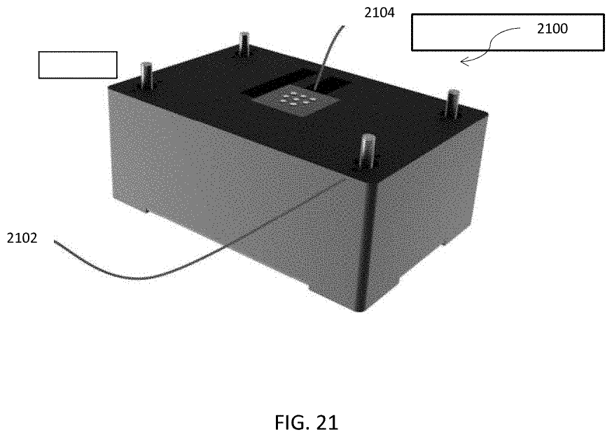

FIG. 21 shows a generic mounting head 2100 different types of tool modules according to an embodiment. The mounting head includes motor-driven rotating threaded rods 2102 in position to engage with the screw holes 2004 in the plate, and pads 2104 for making electrical contact with the electrical contacts 2006 on the plate.

As shown, for example, in FIG. 18A, the laser module 1800 includes a green button 2106 and accompanying green LED 2108 and a red button 2110 and red LED 2112. The green button may be pressed to attach the module to the plate, and the red button to disengage. The LEDs may blink to indicate the operation of attaching or detaching, and remain solid when the module is effectively attached or detached.

Each threaded rod is motor-driven. When attaching the tool module to the plate, the rods are aligned with the holes, and the green button pressed. As the module approaches but before contacting the plate, the electrical contacts, which may be spring-loaded, may make contact with the pads. The connection may be used to identify the type of module, as well as send instructions to the tool during operation. The mounting procedure is autocalibrating. The current in the motors can be used the torque in each rod. When a threshold torque is reached in each motor, the gear disengages. When the gears on all four motors are disengaged, the module is mounted, which may be indicated by the LED.

Alternatively, a limit switch could be proved on each corner of the module, and when the module makes a physical connection, it would trigger a limit sensor, which could be, for example, an eddy current sensor via a loop (or induction sensor), magnetic sensor, or positional sensor that may use laser beam/light and time of light.

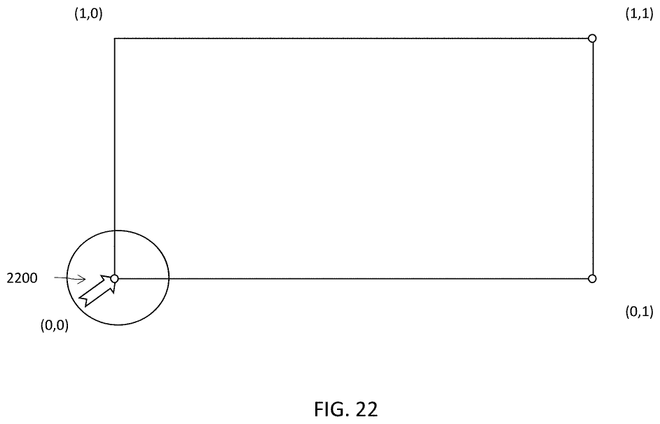

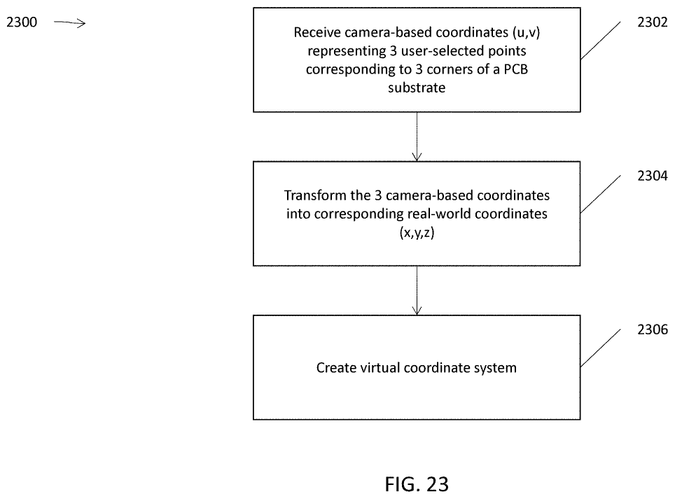

The camera 1906 may be used for an optical registration operation 2300, as shown in FIG. 23. In an exemplary laser lithography operation, the user places a prepreg onto the build plate, rigidly fixing it onto plate, e.g., using tape. The user then starts the camera system and an image dialog program on the computer, which may allow the user to view video and images from the camera and control the gantry system via up, down, left, right commands (at unit steps) using a user input device, e.g., a mouse. The user then registers three points 2302 using the pointer 2200, e.g., corners (0,0), (0,1), and (1,0), as shown in FIG. 22.

For each selected point, the system receives the pointer position and transforms it into camera coordinates [u, v] and transform them into real world coordinates [x, y, z] based on mouse position and move to point [x, y, z] 2304.

To perform the transformation, we assume that we have a calibrated camera, where camera intrinsic and extrinsic parameters have been recovered via a standard camera calibration routine.

A mathematical model describing the transform between camera image space and world space is given by:

$$[ \begin{matrix}x \\ y \\ z\end{matrix} ] = R [ \begin{matrix}X \\ Y \\ Z\end{matrix} ] + t$$

$${x}^{′} = x / z$$

$${y}^{′} = y / z$$

$${x}^{″} = {x}^{′} \frac{1 + {k}_{1} {r}^{2} + {k}_{2} {r}^{4} + {k}_{3} {r}^{6}}{1 + {k}_{4} {r}^{2} + {k}_{5} {r}^{4} + {k}_{6} {r}^{6}} + 2 {p}_{1} {x}^{′} {y}^{′} + {p}_{2} ( {r}^{2} + 2 {{x}^{′}}^{2} )$$

$${y}^{″} = {y}^{′} \frac{1 + {k}_{3} {r}^{2} + {k}_{2} {r}^{4} + {k}_{3} {r}^{6}}{1 + {k}_{4} {r}^{2} + {k}_{5} {r}^{4} + {k}_{6} {r}^{6}} + {p}_{1} ( {r}^{2} + 2 {{y}^{′}}^{2} ) + 2 {p}_{2} {x}^{′} {y}^{′}$$

$$where {r}^{2} = {{x}^{′}}^{2} + {{y}^{′}}^{2} \\ u = {f}_{x} * {x}^{″} + {c}_{x} \\ v = {f}_{y} * {y}^{″} + {c}_{y}$$

Where camera parameters p1, p2, k1, k2, k3, k4, k5, and k6 have been previously recovered by a camera calibration routine along with fx, fy, cx, cy (intrinsic properties).

We define x, y, and z to be world coordinates and u, v to be camera coordinates. Given points u, and v, we are then interested in recovering x, y, and z (world coordinates).

Given image points u and v, we then recover x, y, and z.

[u, v]→[x, y, z]

Once the three points are transformed into world coordinates, a virtual coordinate system is then created 2306. The user can then load the laser module, load the appropriate Gerber file, and start the operation.

For a two-sided lithography operation, the user can remove the prepeg, physically flip it, and place it back onto the build plate to image the underside. The user can then repeat the optical registration operation using the same four corners of the physical prepreg, i.e., in this case, the three selected points would be (0,0), (1,1), and (1,0).

Although the above embodiments have described operations in PCB processing, the various apparatus, methods, hardware, and software described above could be implemented in a variety of different fabrication applications, for example, computer numerical control (CNC) milling, 3-D printing, etc.

While the making and using of various embodiments of the present invention are discussed in detail below, it should be appreciated that the present invention provides many applicable inventive concepts that can be embodied in a wide variety of specific contexts. The principal features of this invention may be employed in various embodiments without departing from the scope of the invention. Those of ordinary skill in the art will recognize numerous equivalents to the specific procedures described herein. The specific embodiments discussed herein are merely illustrative of specific ways to make and use the invention and do not delimit the scope of the invention.

The terms “controller,” “control circuit,” and “control circuitry” as used herein may refer to, be embodied by or otherwise included within a machine, such as a general purpose processor, a digital signal processor (DSP), an application specific integrated circuit (ASIC), a field programmable gate array (FPGA) or other programmable logic device, discrete gate or transistor logic, discrete hardware components, or any combination thereof designed and programmed to perform or cause the performance of the functions described herein. A general purpose processor can be a microprocessor, but in the alternative, the processor can be a controller, microcontroller, or state machine, combinations of the same, or the like. A processor can also be implemented as a combination of computing devices, e.g., a combination of a DSP and a microprocessor, a plurality of microprocessors, one or more microprocessors in conjunction with a DSP core, or any other such configuration.

As will be appreciated by those ordinary skilled in the art, the foregoing example, demonstrations, and method steps may be implemented by suitable code on a processor base system, such as general purpose or special purpose computer. It should also be noted that different implementations of the present technique may perform some or all the steps described herein in different orders or substantially concurrently, that is, in parallel. Furthermore, the functions may be implemented in a variety of programming languages. Such code, as will be appreciated by those of ordinary skilled in the art, may be stored or adapted for storage in one or more tangible machine readable media, such as on memory chips, local or remote hard disks, optical disks or other media, which may be accessed by a processor based system to execute the stored code. Note that the tangible media may comprise paper or another suitable medium upon which the instructions are printed. For instance, the instructions may be electronically captured via optical scanning of the paper or other medium, then compiled, interpreted or otherwise processed in a suitable manner if necessary, and then stored in a computer memory.

1. A tool module comprising:
a housing;
a plurality of threaded rods, each rod connected to a motor operative to disengage when a an indication of engagement is achieved;
one or more electrical contacts for receiving control instructions; and
a user interface to control the motors.

2. The tool module of claim 1, wherein the user interface is a button.

3. The tool module of claim 1, further comprising an indicator to indicate that all motors have disengaged.

4. The tool module of claim 3, wherein the indicator comprises an LED.

5. The tool module of claim 1, wherein the indication of engagement comprises a threshold torque.

6. The tool module of claim 1, wherein the indication of engagement comprises a signal from a limit sensor.

7. A method comprising:
receiving camera-based coordinates representing three user-selected points corresponding to three corners of a PCB substrate;
transforming the three camera-based coordinates into corresponding real world coordinates; and
creating a virtual coordinate system using the real world coordinates.

8. A non-transient computer readable medium containing program instructions for causing a computer to perform the method of:
receiving camera-based coordinates representing three user-selected points corresponding to three corners of a PCB substrate;
transforming the three camera-based coordinates into corresponding real world coordinates; and
creating a virtual coordinate system using the real world coordinates.
